(19) United States
(12) Patent Application Publication
(10) Pub. No.: US 2013/0328448 A1
(43) Pub. Date: Dec. 12, 2013

(54) PIEZO ACTUATOR WITH PROTECTION AGAINST ENVIRONMENTAL INFLUENCES

(71) Applicants: Reinhard Gabl, Kufstein (AT); Wolfgang Pahl, Munchen (DE); Anton Leidl, Hohenbrunn (DE)

(72) Inventors: Reinhard Gabl, Kufstein (AT); Wolfgang Pahl, Munchen (DE); Anton Leidl, Hohenbrunn (DE)

(73) Assignee: EPCOS AG, München (DE)

(21) Appl. No.: 13/993,311

(22) PCT Filed: Nov. 30, 2011
(86) PCT No.: PCT/EP11/71422

§ 371 Date: Aug. 26, 2013

(30) Foreign Application Priority Data
Dec. 15, 2010 (DE) 10 2010 054 589.9

(51) Int. Cl. H01L 41/053; H01L 41/273; H01L 41/083

(52) U.S. Cl. CPC H01L 41/0533; H01L 41/083; H01L 41/273
USPC 310/340; 29/25.35

(57) ABSTRACT

A piezo actuator with protection against environmental influences comprises a layer stack (1) of piezoelectric material layers (10) and interposed electrode layers (20). The piezo actuator furthermore comprises a first and a second material layer (31, 32) composed in each case of a material which exhibits smaller amount of expansion. than the piezoelectric material layers (10) when a voltage is applied. to the electrode layers (20), and comprises a cover layer (50) composed of a metal material. The layer stack (1) is arranged between the first and second material layers (31, 32). The cover layer (50) surrounds the layer stack (1) and is sputtered onto the first and second material lavers (31, 32).

The invention relates to a piezo actuator with protection against environmental influences, in particular with protection against liquid or gaseous substances. Furthermore, the invention relates to a method for producing a piezo actuator with protection against environmental influences, in particular with protection against liquid or gaseous substances.

A piezo actuator comprises a multiplicity of piezoelectric layers, between which electrode layers are respectively arranged. A deformation of the piezoelectric layers emerges when an electrical voltage is applied to the electrode layers. The piezoelectric layers can expand for example in a main deformation direction along the actuator axis, as a result of which a stroke is generated.

Piezo actuators are often used in the vicinity of liquid or gaseous substances. Exemplary applications are the control of injection valves in engines. Contact of the piezoelectric layers and the electrode layers with the, in many cases aggressive, liquid and/or gaseous substances leads in most cases to the destruction of the piezo actuator or at least to a reduction of the lifetime thereof. For the application of piezo actuators in injection valves, relevant substances are for example water or moisture or else fuels such as diesel or gasoline.

In present-day applications, in particular protection from fuels is brought about by the actuator being housed in a metal cylinder, wherein the interior of the metal cylinder, in particular in the region of the contact connections of the actuator, is sealed in a complex manner. Although the encapsulation thereby obtained can in most cases be embodied in a hermetically impermeable manner, the housing form, owing to the dimensional allowance at the end sides and also at the side faces of the actuator, results in a space requirement that is not suitable for all applications.

Predominantly motivated by reduction of the number of components of an injector and the cost saving associated therewith there is an increasingly emerging trend toward operating the piezo actuator directly with fuel flowing around it, in so-called wet operation, at a high ambient pressure. This operating condition requires that the actuator is sealed as far as possible impermeably, preferably hermetically and at the same time in a manner that saves as much space as possible. In order to minimize the space requirement for the sealing of the piezo actuator, the actuator in most cases cannot be arranged in a separate housing.

It is desirable to specify a piezo actuator with protection against environmental influences which is embodied in a manner that saves as much space as possible, and which nevertheless has high impermeability with respect to liquid or gaseous substances. Furthermore, the intention is to specify a method for producing a piezo actuator with protection against environmental influences, wherein the piezo actuator is embodied in a manner that saves as much space as possible, and nevertheless has high impermeability with respect to liquid or gaseous substances.

A piezo actuator with protection against environmental influences comprises a layer stack composed of piezoelectric material layers and electrode layers arranged therebetween. Furthermore, the piezo actuator comprises a first and second material ply each composed of a material having a smaller expansion than the piezoelectric material layers when a voltage is applied to the electrode layers, and a cover layer composed of a material composed of metal. The layer stack is arranged between the first and second material plies. The cover layer surrounds the layer stack and is sputtered onto the first and second material plies.

The sputtering of the cover layer over the layer stack, and in particular the sputtering of the cover layer onto the material plies, which can contain piezoelectrically inactive materials, for example, gives rise to a virtually hermetically impermeable and fixed connection between the cover layer and the material plies. Since, as a result of the continuous metal and respectively ceramic enclosure, a fixed connection between the materials is created and no abutment joints are created between the materials, it is possible to achieve a virtually totally impermeable sealing of the layer stack composed of the piezoelectric layers relative to contact with liquid or gaseous substances.

A method for producing a piezo actuator with protection against environmental influences comprises a step of providing a layer stack composed of piezoelectric material layers and electrode layers arranged therebetween and a first and second material ply each composed of a material having a smaller expansion than the piezoelectric material layers when a voltage is applied to the electrode layers, wherein the layer stack is arranged between the first and second material plies. A cover layer composed of a material composed of metal is arranged over the layer stack. The cover layer is sputtered onto the first and second material plies.

Further embodiments of the piezo actuator and of the method for producing the piezo actuator can be gathered from the dependent claims.

The invention is explained in greater detail below with reference to figures showing exemplary embodiments of the present invention.

In the figures:

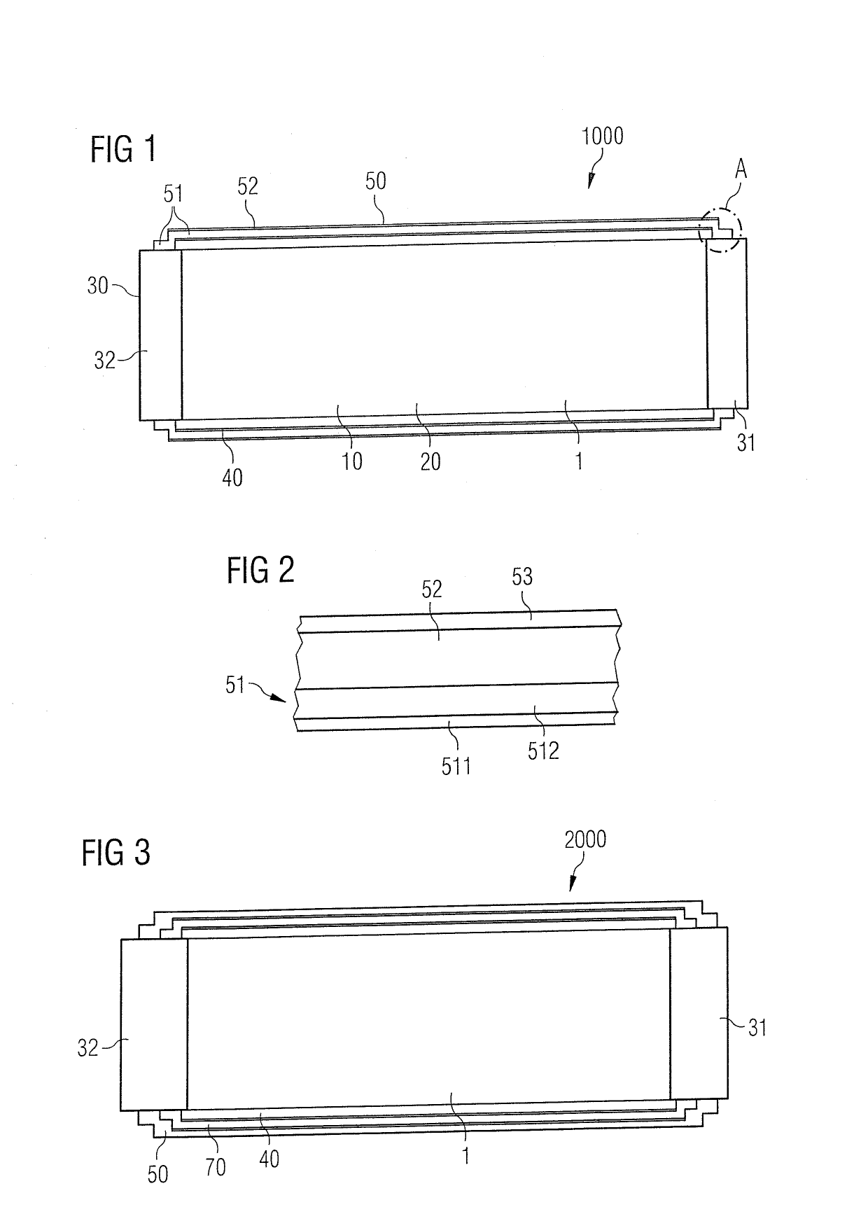

FIG. 1 shows an embodiment of a piezo actuator with protection against environmental influences,

FIG. 2 shows an embodiment of a cover layer for sealing a piezo actuator relative to the environment,

FIG. 3 shows a further embodiment of a piezo actuator with protection against environmental influences,

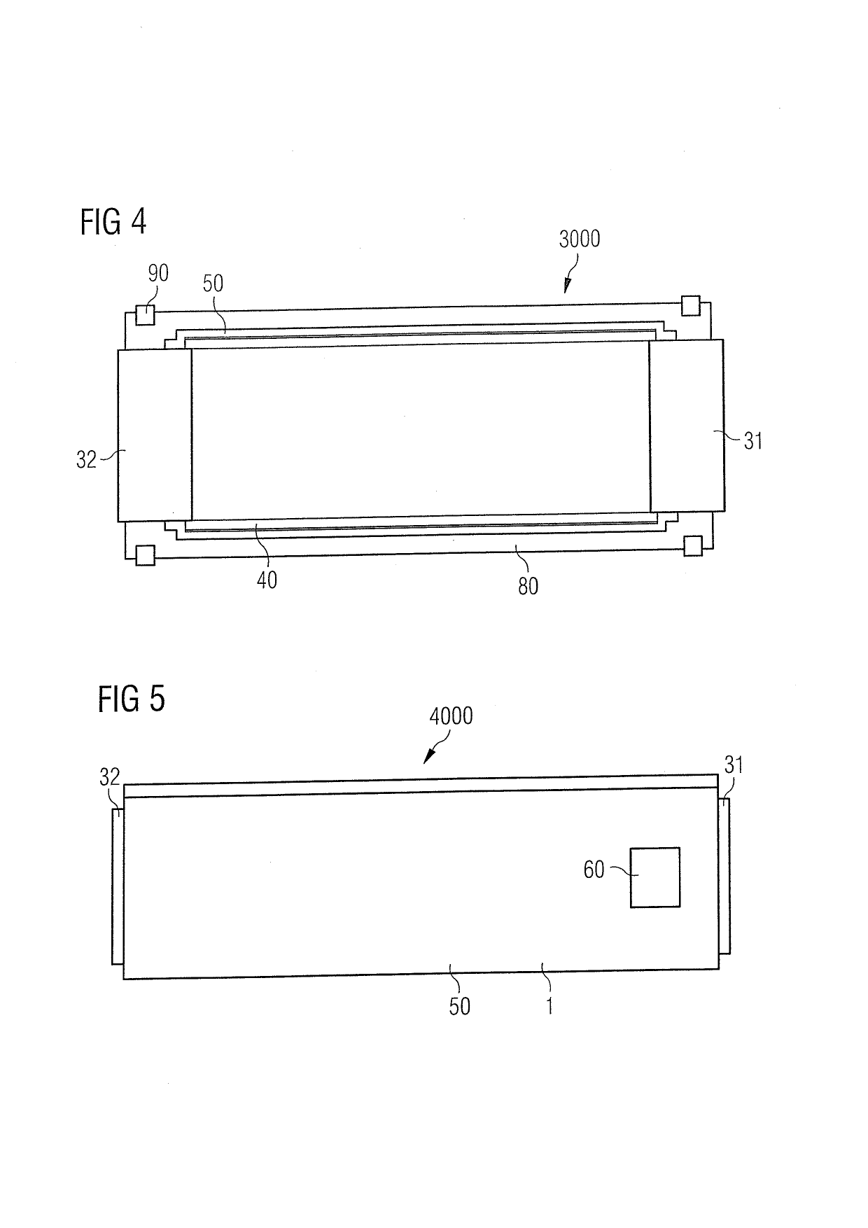

FIG. 4 shows a further embodiment of a piezo actuator with protection against environmental influences,

FIG. 5 shows an embodiment of a piezo actuator sealed relative to the environment, with a cutout for making contact with the piezo actuator,

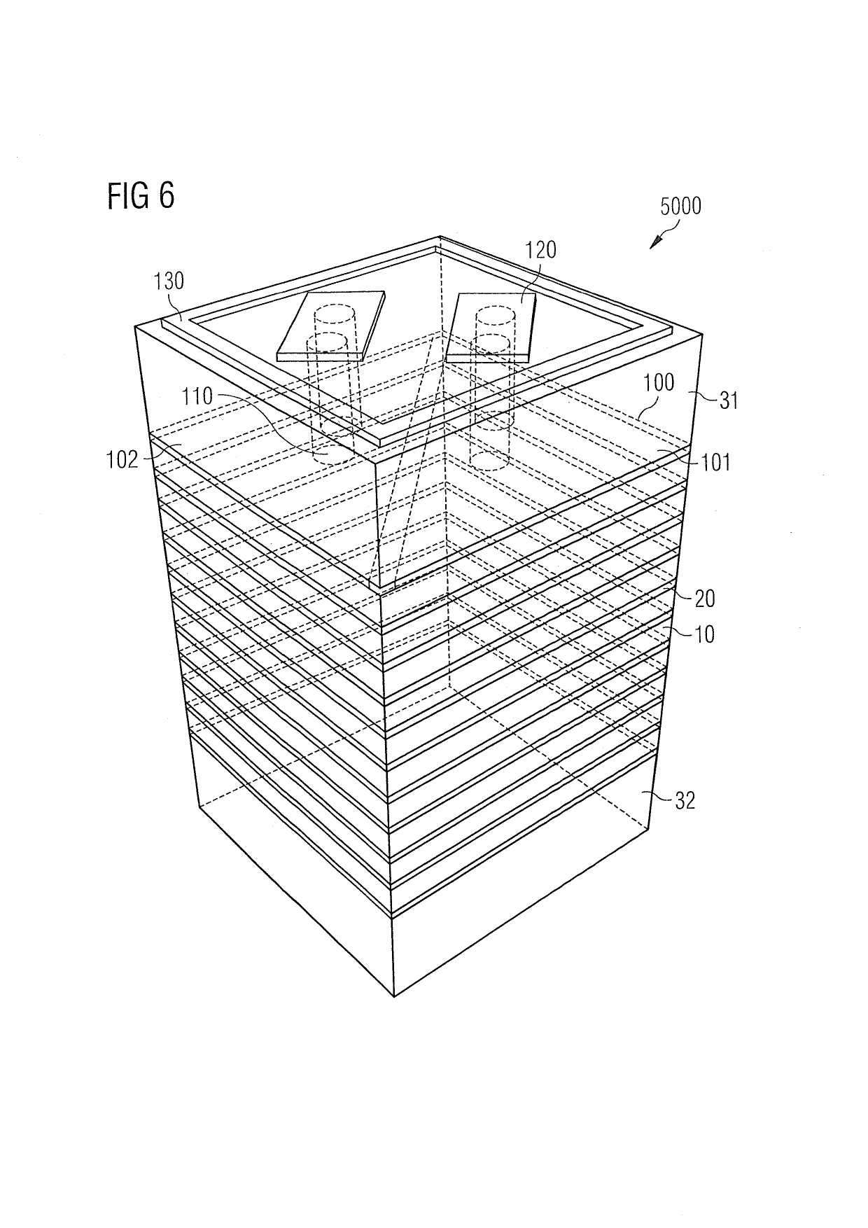

FIG. 6 shows an embodiment of a piezo actuator with contact connections on an end side of the piezo actuator,

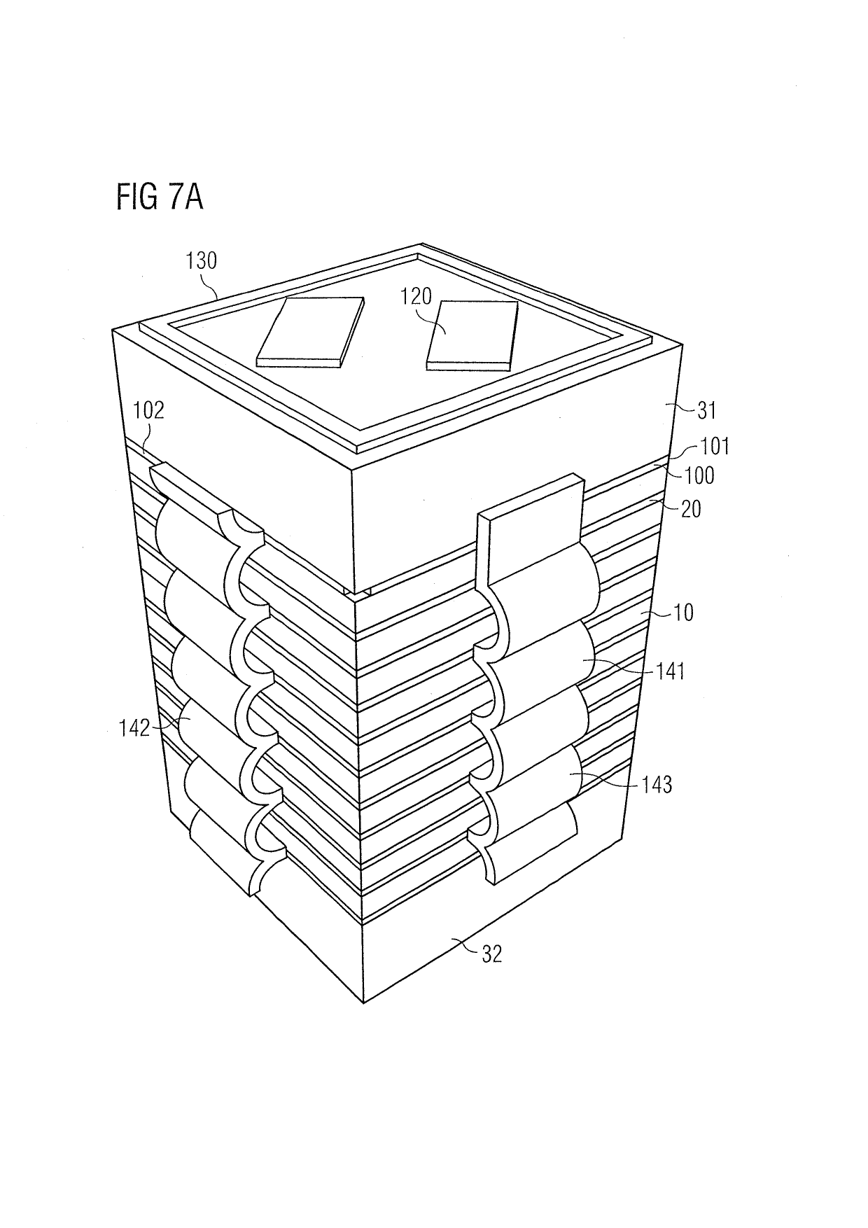

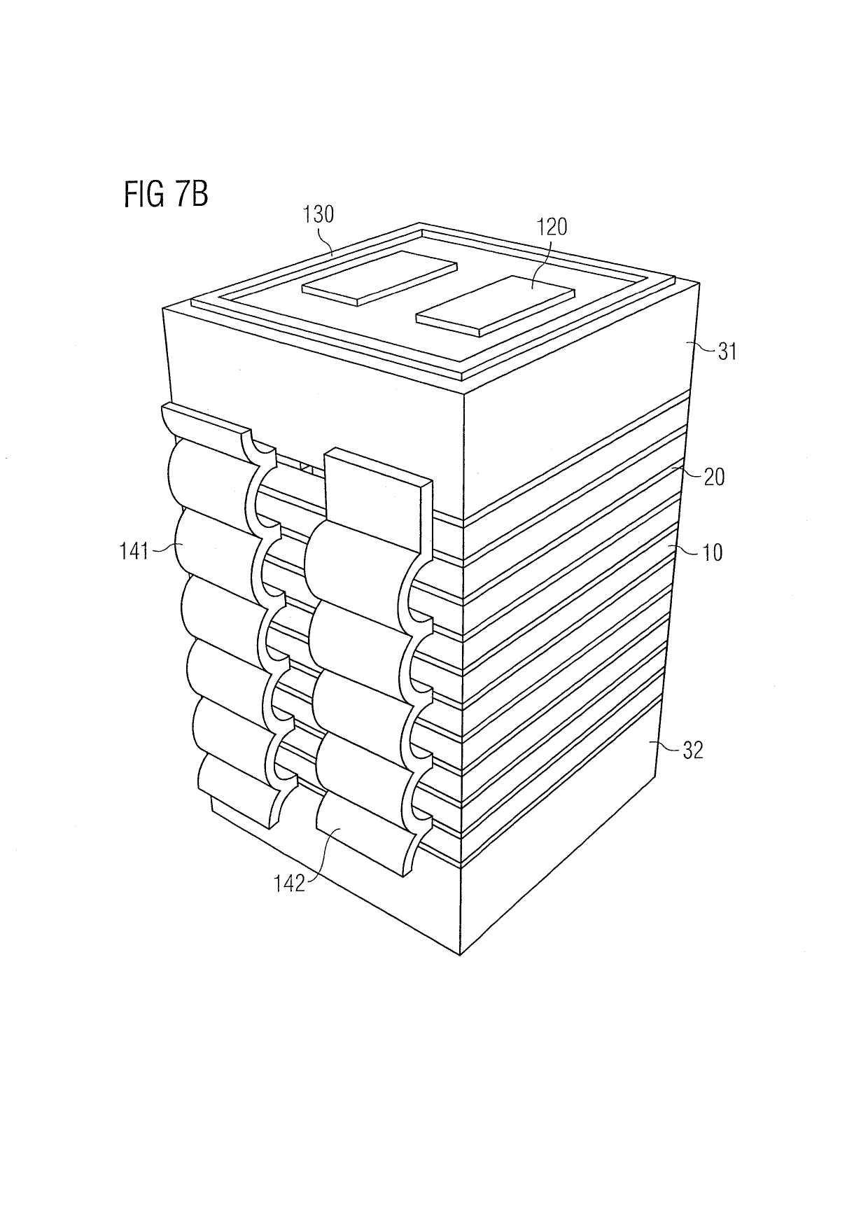

FIG. 7A shows an embodiment of a piezo actuator with a conductor track for making contact with the electrode layers of the piezo actuator,

FIG. 7B shows a further embodiment of a piezo actuator with a conductor track for making contact with electrode layers of the piezo actuator,

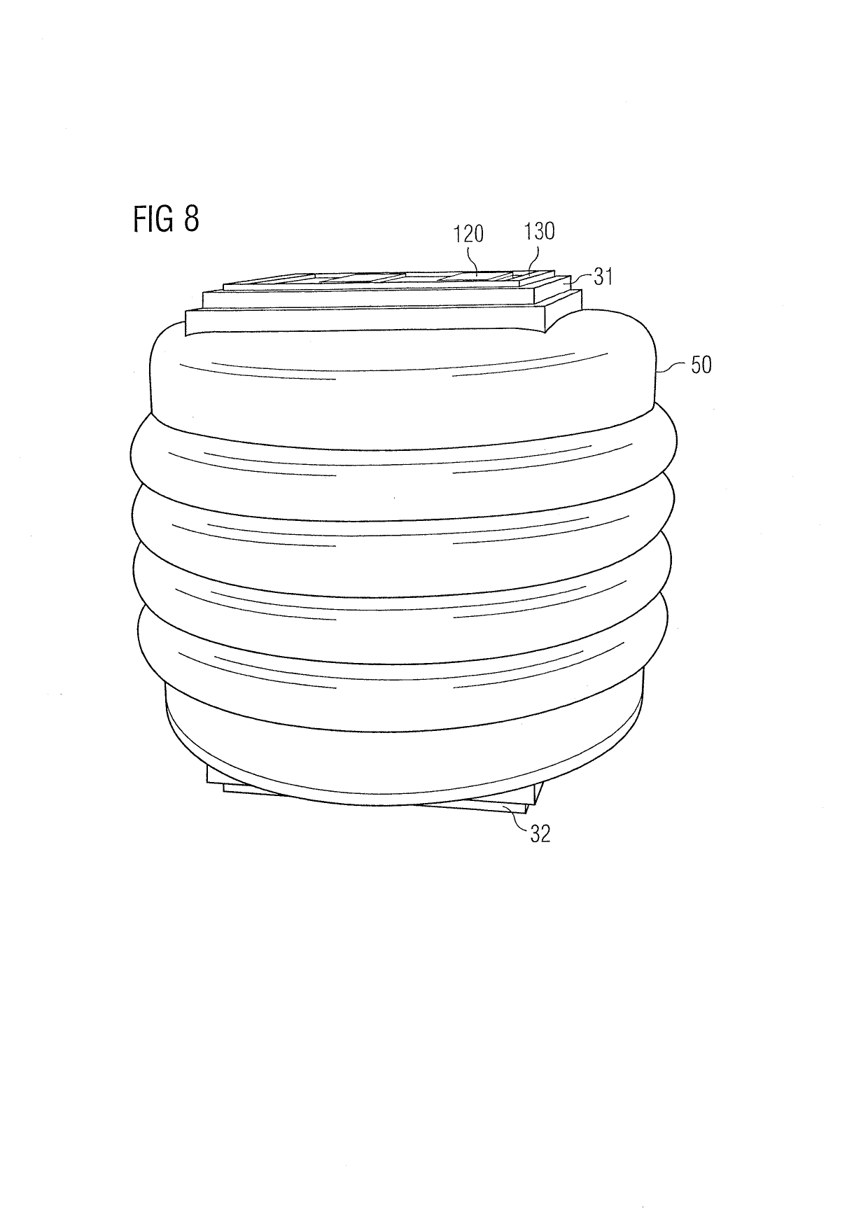

FIG. 8 shows an embodiment of a piezo actuator with protection against environmental influences.

FIG. 1 shows an embodiment 1000 of a piezo actuator comprising a layer stack 1 composed of piezoelectric material layers 10 and electrode layers 20 arranged therebetween. The piezoelectric layers expand when a voltage is applied to the electrode layers, as a result of which a stroke is generated. The layer stack 1 is arranged between a material ply 31 and a material ply 32. The material ply 31 and the material ply 32 terminate the layer stack on both sides in the direction of the longitudinal axis of the actuator. The material plies 31 and 32 can be embodied as material blocks composed of a material having a smaller expansion than the piezoelectric layers 10 when a voltage is applied to the electrode layers 20. A smaller expansion within the meaning of the embodiments of the piezo actuator should also be understood to include the fact that the material plies exhibit no expansion when a voltage is applied to the piezoelectric layers. The material plies 31 and 32 can be embodied for example in each case as a passive cover ply composed of an inactive ceramic or a non-piezoelectric ceramic.

For insulating the layer stack 1, in particular the electrode layers 20, an insulation or passivation layer 40 is arranged over the layer stack 1. The insulation layer 40 is formed from a non-conductive material. By way of example, a film can be used as insulation layer, said film being adhesively bonded or laminated onto the layer stack. The insulation layer 40 can comprise a material composed of a polymer, for example composed of polyimide. One such material is sold under the trade name Kapton, for example. As an alternative thereto, it is possible to use materials which can be applied to the layer stack 1 by spraying, dipping or coating.

Furthermore, a cover layer 50 is applied over the layer stack. In accordance with the embodiment shown in FIG. 1, the cover layer 50 is arranged on the insulation layer 40. The cover layer 50 can comprise a material composed of metal. The cover layer can comprise a sublayer 51, for example, which is sputtered onto the insulation layer 40. The insulation layer is firstly designed to insulate the electrode layers 20 of the layer stack 1 from the environment, and secondly embodied in a suitable manner to serve as a support for the sputtering layer 51. For this purpose, the insulation layer preferably has a thickness of 10 μm to 500 μm. The sublayer 51 extends beyond the end region of the insulation layer 40 and is sputtered onto the material plies 31 and 32. The sputtering layer 51 can be sputtered with a thickness of a few 100 nm to a few micrometers over the insulation layer 40 and the material plies 31 and 32 adjoining the layer stack 1. A further sublayer 52 can be arranged over the sputtering layer 51. The sublayer 52 is preferably arranged on the sputtering layer 51 by electrodeposition of a metal, for example of copper. The cover layer 50 therefore surrounds the layer stack 1.

As a result of the sputtering process, an impermeable connection arises at a region A between the cover layer 50 composed of the metal and the material plies 31 and 32. The sputtering layer 51 and the electrolytic reinforcement layer 52 arranged thereon thus make possible hermetic encapsulation of the layer stack 1. The piezoelectric material layers 10 and the electrode layers 20 are thereby protected to the greatest possible extent against the penetration or contact of harmful substances, in particular liquid or gaseous substances.

FIG. 2 shows an embodiment of the cover layer 50 composed of different layers. The sublayer 51 can comprise an adhesion promoter layer 511, for example a layer composed of titanium or chromium, over which a reinforcement layer 512, for example a layer composed of copper, is subsequently arranged. The thickness of the sputtering layer 51 is for example a few tenths of a pm to a few pm, for example between 10 μm and 100 μm. The sublayer 52 is electrodeposited over the sputtering layer 51 in a subsequent process. Copper, for example, can be used as material for the electroplating layer 52. The sublayers 51 and 52 can together have a layer thickness of between 10 μm and 100 μm, for example. In order to protect the electroplating layer 52 against corrosion, the cover layer 50 can comprise a further sublayer 53. The sublayer 53 can be a layer composed of nickel, for example, which is likewise electrodeposited on the sublayer 52.

FIG. 3 shows an embodiment 2000 of the piezo actuator. Components identical to those in FIG. 1 are provided with the same reference signs. In contrast to the embodiment shown in FIG. 1, in the embodiment in accordance with FIG. 3, an intermediate layer 70 is provided between the insulation layer 40 and the cover layer 50. The intermediate layer 70 can be for example a film composed of a thermoplastic material, said film serving as a support for applying the sputtering layer 51. In the case of the embodiment shown in FIG. 3, it is possible to separately optimize the insulation properties of the passivation layer 40 and the surface properties of the intermediate layer 70.

FIG. 4 shows an embodiment 3000 of the piezo actuator with a sealing of the layer stack 1 relative to the environment. Components identical to those in the embodiments in FIGS. 1 and 3 are provided with the same reference signs. In contrast to the embodiment shown in FIG. 1, a material 80 composed of a polymer is arranged over the cover layer 50 and the material plies 31 and 32. By way of example, a sleeve composed of a polymer material, in particular composed of Teflon, can be applied as an outer enclosure of the cover layer 50 and of the material plies 31 and 32. The polymer sleeve can be a shrinkable sleeve, for example, which is shrunk onto the cover layer 50 and the passive cover plies 31 and 32 by the action of heat.

The sleeve composed of the polymer material can be sealed in the passive regions of the piezo actuator, that is to say in the region of the passive cover plies 31 and 32, with clamps, for example with sealing rings 90. Arranging the material composed of polymer as an outer layer of the piezo actuator achieves protection of the cover layer 50 relative to damage which would possibly result in a lack of impermeability. For the sake of completeness, it should be noted that a material composed of a polymer can be applied as an outer protective layer also over the embodiment of a piezo actuator as shown in FIG. 3.

FIG. 5 shows a plan view of an embodiment 4000 of the piezo actuator in which the layer stack 1 is sealed against environmental influences by means of the cover layer 50. Components of the piezo actuator that are identical to those in the previous figures are again provided with the same reference signs. In contrast to the previous embodiments, a cutout 60 for making contact with the electrode layers of the layer stack 1 is provided in the cover layer 50. Since the cutout 60 is fashioned with a small area, the window for contact-making can be sealed by choosing corresponding sealing materials which would not be appropriate for the entire passivation of the actuator, in order to achieve the best possible tightness. By way of example, a material composed of epoxy can be used for this purpose.

FIG. 6 shows an embodiment 5000 of the piezo actuator. For better illustration of the embodiment shown, the insulation layer 40 and the cover layer 50 are not illustrated in FIG. 6. The piezo actuator comprises the layer stack 1 composed of the piezoelectric material layers 10 and the electrode layers 20 arranged therebetween. At the top side and underside of the layer stack 1, the material plies 31 and 32 are arranged as passive cover plies, for example composed of an inactive ceramic. The inactive ceramic material of the cover plies 31 and 32 exhibits a smaller expansion than the piezoelectric layers when a voltage is applied to the piezoelectric layers 10, which, within the meaning of the embodiments of the piezo actuator, also includes the case where the cover plies exhibit no expansion at all. The passive cover plies are embodied as end caps of the piezo actuator.

In order to make contact between the electrode layers 20 and an exciting voltage, a wiring layer 100, for example a layer composed of a conductive material, is provided on the top side of the layer stack 1. The wiring layer 100 can have two sublayers 101 and 102 arranged in a manner insulated from one another. Each of the sublayers 101 and 102 is connected to a contact connection 120 for applying an electrical voltage to the piezo actuator. The connection between the contact connections 120 and the sublayers 101 and 102 of the wiring layer 100 is effected by holes 110, so-called vias, which contain a conductive material. In order to connect a plug connector to the piezo actuator, a solder sealing ring 130 is provided on the passive cover ply 31, with which ring the plug connector can be soldered, for example.

FIG. 7A shows, for the embodiment 5000, an embodiment variant for connecting the electrode layers 20 to the mutually insulated sections 101 and 102 of the wiring layer 100. A conductor track 141 and a conductor track 142 are provided along different side faces of the piezo actuator. The conductor tracks can be embodied for example in each case as a flexible copper busbar. Each of the conductor tracks 141 and 142 connects each second and thus next but one electrode layer 20. For feeding the voltage, the conductor tracks are connected to the two sections 101 and 102 of the wiring layer 100.

In order to withstand the dynamic loading during an expansion of the layer stack 1, the conductor tracks 141 and 142 are in each case embodied in a caterpillar-like manner or with arcuate sections 143. The arcuate sections can be embodied in a rounded or angular manner. In particular, the conductor tracks are embodied in such a way that a respective arc of the conductor track 141, 142 connects each next but one electrode layer 20. Since, by means of the arcuate curve of the conductor tracks 141 and 142, only each second electrode layer is contact-connected to one of the conductor tracks, this makes it possible to form the electrode layers 20 between the piezoelectric layers 10 in such a way that the electrode layers in each case cover the entire area of the piezoelectric layers. It is thus possible to manufacture the layer stack 1 without relatively high complexity. Moreover, the piezoelectric coupling is more effective since the entire cross section of the stack is driven without edge cutouts.

In order to manufacture the conductor track 141 and 142, firstly a photoresist layer can be applied to the layer stack 1. The regions of the electrode layers are subsequently uncovered by laser irradiation. A seed layer is sputtered over the resist layer and the uncovered electrode layers. The seed layer can be laser-structured, such that only the regions at which the conductor tracks 141 and 142 are formed remain. The layer construction of the conductor tracks 141 and 142 can subsequently be effected by layer electrodeposition. The resist can remain under the bridge-shaped curves 143 of the conductor tracks 141 and 142 or be removed. The resist layer under the conductor tracks can serve as a reinforcement layer for the busbars 141 and 142.

FIG. 7B shows a further embodiment variant of the embodiment 5000 of the piezo actuator. In the case of the embodiment variant shown in FIG. 7B, the two conductor tracks are arranged on a common side of the piezo actuator. This embodiment has the advantage that the two busbars can be jointly processed on the common surface of a side face of the piezo actuator.

FIG. 8 shows the piezo actuator of the embodiment 5000 in which the layer stack 1 and the conductor tracks 141 and 142 are surrounded firstly by an insulation layer and a cover layer. Only the outer cover layer 50 is illustrated in FIG. 8. The cover layer comprises a sputtering layer sputtered over the insulation layer and over the passive cover plies adjoining the layer stack 1. A reinforcement layer can be produced over the sputtering layer by layer electrodeposition. The complete layer stack is hermetically encapsulated by the sputtering layer and the electrolytic reinforcement. The contour of the cover layer 50 as shown in FIG. 8 enables a good elastic deformability in the direction of the longitudinal axis of the actuator. Said contour can be obtained for example by means of a corresponding injection/mold tool for the underlying insulation layer. Alternatively, a dip resist coating can also be applied.

The embodiments of the piezo actuator shown require a minimal space requirement in conjunction with the highest possible impermeability relative to the environment. This is realized by virtue of the fact that, circumferentially around the layer stack and the adjoining material plies, a continuous metal and respectively ceramic enclosure is realized without abutment joints. What is essential in this case is, in particular, the fixed and impermeable connection at the transition between the inactive ceramic of the material plies and the cover layer composed of metal, which is realized by means of the sputtering process.

### LIST OF REFERENCE SIGNS

1 Layer stack

10 Piezoelectric material layers

20 Electrode layers

31, 32 Material plies/passive cover plies

40 Insulation layer/passivation layer

50 Cover layer

51 Sublayer/sputtering layer

52 Sublayer/electroplating layer

60 Cutout for making contact

70 Intermediate layer

80 Polymer sleeve

90 Sealing ring

100 Wiring layer

101, 102 Sections of the wiring layer

110 Hole/via

120 Contact connection

130 Solder sealing ring

141, 142 Conductor tracks

1. A piezo actuator with protection against environmental influences, comprising:
a layer stack composed of piezoelectric material layers and electrode layers arranged therebetween;
a first and second material ply each composed of a material which has a smaller expansion than the piezoelectric material layers when a voltage is applied to the electrode layers; and
a cover layer composed of a material composed of metal,
wherein the layer stack is arranged between the first and second material plies,
wherein the cover layer surrounds the layer stack, and
wherein the cover layer is sputtered onto the first and second material plies.

2. The piezo actuator according to claim 1, further comprising:
an insulation layer composed of a non-conductive material for insulating the electrode layers,
wherein the insulation layer is arranged between the layer stack and the cover layer.

3. The piezo actuator according to claim 1 or 2, wherein the insulation layer is embodied as a film composed of a polymer, in particular composed of polyimide.

4. The piezo actuator according to claim 1, comprising:
an intermediate layer composed of a material composed of a polymer,
wherein the intermediate layer is arranged between the insulation layer and the cover layer.

5. The piezo actuator according to claim 1, wherein the cover layer comprises a first sublayer and a second sublayer,
wherein the first sublayer is sputtered onto the first and second material plies, and
wherein the second sublayer is arranged on the first sublayer by electrodeposition.

6. The piezo actuator according to claim 5, wherein the first sublayer of the cover layer comprises an adhesion promoter layer, in particular a layer composed of a material composed of titanium and/or chromium, and a reinforcing layer, in particular a layer composed of a material composed of copper, arranged on the adhesion promoter layer.

7. The piezo actuator according to claim 5 or 6,
wherein the cover layer comprises a third sublayer, and
wherein the third sublayer is designed to protect the second sublayer against corrosion.

8. The piezo actuator according to claim 1, wherein a material composed of a polymer, in particular a shrinkable sleeve, is arranged over the cover layer.

9. The piezo actuator according to claim 1, wherein the first and second material plies contain a material composed of a ceramic, in particular composed of a non-piezoelectric ceramic.

10. The piezo actuator according to claim 1, further comprising:
a contact connection arranged on at least one of the first and second material plies;
a conductive layer arranged between the layer stack and the at least one first and second material ply; and
a plated-through hole, which runs through the at least one first and second material ply and connects the contact connection to the conductive layer.

11. The piezo actuator according to claim 10, further comprising:
a conductor track having a multiplicity of curved sections,
wherein the curved sections of the conductor track are respectively contact-connected to each next but one of the electrode layers, and
wherein the electrode layers are arranged between the piezoelectric layers in such a way that each of the electrode layers covers the entire area of the piezoelectric layers arranged above and below it in the layer stack.

12. A method for producing a piezo actuator with protection against environmental influences, comprising:
providing a layer stack composed of piezoelectric material layers and electrode layers arranged therebetween and a first and second material ply each composed of a material having a smaller expansion than the piezoelectric material layers when a voltage is applied to the electrode layers, wherein the layer stack is arranged between the first and second material plies;
arranging a cover layer composed of a material composed of metal over the layer stack; and
sputtering the cover layer onto the first and second material plies.

13. The method according to claim 12, further comprising:
arranging an insulation layer, in particular adhesively bonding or laminating a film composed of a polymer, onto the layer stack before the step of applying the cover layer over the layer stacks;
sputtering a first sublayer of the cover layer onto the insulation layer; and
electrodepositing a second sublayer of the cover layer onto the first sublayer.

14. The method according to claim 12, further comprising:
arranging an insulation layer, in particular adhesively bonding or laminating a film composed of a polymer, onto the layer stack;
arranging an intermediate layer, in particular a film composed of a thermoplastic material, on the insulation layer;
sputtering a first sublayer of the cover layer onto the intermediate layer; and
electrodepositing a second sublayer of the cover layer onto the first sublayer.

15. The method according to one of claims 12 to 14, further comprising:
arranging a material composed of a polymer, in particular a shrinkable sleeve, over the cover layer.
